(19) United States
(12) Patent Application Publication
(10) Pub. No.: US 2020/0234730 A1
(43) Pub. Date: Jul. 23, 2020

(54) SPUTTERING TARGET AND METHOD FOR PRODUCING SAME, AND METHOD FOR PRODUCING MAGNETIC RECORDING MEDIUM

(71) Applicant: JX Nippon Mining & Metals Corporation, Tokyo (JP)

(72) Inventor: Shin-ichi OGINO, Ibaraki (JP)

(73) Assignee: JX Nippon Mining & Metals Corporation, Tokyo (JP)

(21) Appl. No.: 16/628,896

(22) PCT Filed: Sep. 28, 2018
(86) PCT No.: PCT/JP2018/036501

§ 371 Date: Jan. 6, 2020

(30) Foreign Application Priority Data
Mar. 27, 2018 (JP) 2018060338

(51) Int. Cl. G11B 5/851; B22F 3/15; B22F 9/08; C22C 29/16; C23C 14/34; C22C 1/04; C22C 1/05; C22C 5/04

(52) U.S. Cl. CPC G11B 5/851; B22F 3/15; B22F 9/08; C22C 5/04; C23C 14/3414; C22C 1/0466; C22C 1/05; C22C 29/16

(57) ABSTRACT

The present disclosure provides a sputtering target containing one or more metals of Fe, Co, Cr, and Pt, and one or more of C and BN, with less generation of particles, and a method for producing the same. A sputtering target including: one or more metallic phases selected from a group consisting of Fe, Co, Cr, and Pt; and one or more nonmetallic phases selected from a group consisting of C and BN, wherein the sputtering target satisfies: A≤40, and A/B≤1.7 in which A represents the number of boundaries between the metallic phases and the nonmetallic phases on a line segment having a length of 500 μm drawn in a vertical direction, in a structure photograph; and B represents the number of boundaries between the metallic phases and the nonmetallic phases on a line segment having a length of 500 μm drawn in a horizontal direction, in the structure photograph.

### TECHNICAL FIELD

The present disclosure relates to a sputtering target, a method for producing the same, and a method for producing a magnetic recording medium. More particularly, the present disclosure relates to a sputtering target containing one or more metals of Fe, Co, Cr, and Pt and one or more of C and BN, and to a method for producing the same, as well as to a method for producing a magnetic recording medium.

### BACKGROUND ART

In the field of magnetic recording media represented by HDDs (Hard Disk Drives), materials based on Co, Fe or Ni that is a ferromagnetic metal are used as materials of magnetic thin films responsible for recording. For example, Co—Cr based or Co—Cr—Pt based ferromagnetic alloys containing Co as a main component have been used for recording layers of hard disks employing a longitudinal magnetic recording system. Further, composite materials composed of the Co—Cr—Pt based ferromagnetic alloy containing Co as a main component and nonmagnetic inorganic grains are widely used for recording layers of hard disks employing a perpendicular magnetic recording system which has been recently put to practical use. The magnetic thin films of the magnetic recording media such as hard disks are often produced by sputtering the ferromagnetic sputtering targets containing the above materials, in terms of high productivity.

On the other hand, recording density of the magnetic recording media is rapidly increasing every year, and the surface density is presently 100 Gbit/in², but it will reach 1 Tbit/in² in the future. When the recording density reaches 1 Tbit/in², the size of the recorded bit will be lower than 10 nm. In this case, there would be a problem of superparamagnetization due to thermal fluctuation, which would not be sufficiently addressed by the currently used magnetic recording media, for example materials which have improved crystal magnetic anisotropy obtained by adding Pt to the Co—Cr based alloy, or media which have weakened a magnetic bond between magnetic grains by further adding B to those materials, because the grains that stably act as ferromagnets in a size of 10 nm or less should have higher crystal magnetic anisotropy.

For the reasons as described above, a Fe—Pt phase possessing a L1₀ structure is attracting attention as a material for ultrahigh density recording media. Also, the Fe—Pt phase possessing the L1₀ structure can be a material that is suitable for application of recording media, because the Fe—Pt phase possessing the L1₀ structure has excellent corrosion resistance and oxidation resistance. The Fe—Pt phase has an order-disorder transformation point at 1573K, and generally has an L1₀ structure due to rapid ordering reaction even when the alloy is annealed starting from an elevated temperature. When the Fe—Pt phase is used as the material for the ultrahigh density recording media, there is a need for development of a technique for dispersing ordered Fe—Pt grains so as to align their orientations with a density as high as possible, while magnetically isolating the ordered Fe—Pt grains.

Therefore, granular structure magnetic thin films in which the Fe—Pt grains possessing the L1₀ structure are magnetically isolated by nonmagnetic materials such as C (carbon) or BN have been proposed for magnetic recording media of next generation hard disks employing a thermally assisted magnetic recording system. The granular structure magnetic thin film has a structure in which the magnetic particles are magnetically insulated from each other by interposing nonmagnetic materials therebetween. Such a magnetic recording layer is typically formed using a sputtering target. In general, the sputtering target is prepared by pulverizing and mixing Fe—Pt raw material powder and C powder or BN powder, and subjecting the mixed powder to hot press sintering. However, in this case, defects or the like are generated in the structure of the sintered body, which may cause generation of particles during sputtering.

In addition, for the purpose of controlling the magneto crystalline anisotropy (hereinafter referred to as Ku) in the media of next-generation hard disks, a target prepared by mixing one or more of C and BN with an alloy that combines one or more of Fe, Co, Cr, and Pt may be used separately from the Fe—Pt phase possessing the L1₀ structure.

In view of the previous studies, requirements for reducing particles in the sputtering target for next-generation hard disks include: 1) the use of dense alloy raw materials; 2) the use of exfoliated graphite with high crystallinity as carbon raw materials; 3) mixing mildly so as not to cause defects in the carbon raw materials; and 4) to pretreat the alloy raw materials into the form of a flake so to have a layered crystalline structure. In particular, the use of pulverized alloy chip powder treated with a medium stirring mill has been effective for reducing the particles. However, this method causes a problem that sharp edges of the pulverized alloy chip powder provides defects to the carbon raw material and the BN raw material, causing the particles. In addition, prior arts relating to sputtering targets for next generation hard disks include the following patent documents.

### CITATION LIST

Patent Document 1: Japanese Patent Application Publication No. 2015-175025 A
Patent Document 2: Japanese Patent Application Publication No. 2012-214874 A
Patent Document 3: U.S. Patent Application Publication No. 2014/318854 (WO 2013/105647)
Patent Document 4: Japanese Patent Application Publication No. 2012-102387 A
Patent Document 5: U.S. Patent Application Publication No. 2018/019389 (WO 2016/140113)

### SUMMARY OF INVENTION

### Technical Problem

The pretreatment of the pulverized alloy chip powder with the medium stirring mill can provide fine and flaky alloy powder, and a sputtering target produced using the powder can suppress generation of particles to some extent. However, there is room for improvement of the generation of particles. The pulverized alloy chip powder in the prior art is prepared such as by melting Fe and Pt to form an alloy, and then collecting alloy chip powder with a general-purpose lathe, and roughly pulverizing the powder with a brown mill. The produced alloy powder has sharp edges, which causes a problem that the edges provide defects in the carbon raw material when mixed together with the carbon raw material, causing particles.

The present inventor has studied the production of dense raw material powder by using atomized powder in place of the pulverized alloy chip powder. As a result, the present inventor has found a problem that the atomized powder having an excessively large grain diameter tends to be detached during sputtering, and the number of particles is increased. Moreover, when the atomized powder having a large grain diameter and the carbon raw material are pulverized and mixed together in a ball mill, defects may be introduced into the carbon raw material, resulting in an increase in particles. In view of the above problems, the present disclosure provides a sputtering target containing one or more metals of Fe, Co, Cr, and Pt, and one or more of C and ON, with less generation of particles, and a method for producing the same.

### Solution to Problem

As a result of intensive studies, the present inventor has found that the generation of particles during sputtering can be suppressed by using atomized powder with a controlled grain diameter, which is mixed with at least one powder of C and BN, and subjected to hot press sintering to produce a sputtering target.

Based on such findings, the present inventor provides the following inventions:

(Invention 1)

A sputtering target comprising:

one or more metallic phases selected from a group consisting of Fe, Co, Cr, and Pt; and

one or more nonmetallic phases selected from a group consisting of C and BN,

wherein the sputtering target satisfies:

A≤40, and

A/B≤1.7

in which:

A represents the number of boundaries between the metallic phases and the nonmetallic phases on a line segment having a length of 500 μm drawn in a vertical direction, in a structure photograph; and

B represents the number of boundaries between the metallic phases and the nonmetallic phases on a line segment having a length of 500 μm drawn in a horizontal direction, in the structure photograph.

(Invention 2)

The sputtering target according to Invention 1, wherein the sputtering target further comprises one or more metals selected from a group consisting of Ru, Ag, Au, Cu, and Ge.

(Invention 3)

A method for producing a sputtering target, comprising:

a step of atomizing one or more metals selected from a group consisting of Fe, Co, Cr, and Pt to obtain atomized powder;

a step of processing the atomized powder so as to have a median diameter of 40 μm or less;

a step of mixing the atomized powder with at least one powder selected from a group consisting of C and BN; and

a step of sintering the mixed powder by hot pressing.

(Invention 4)

The method according to Invention 3, wherein the step of processing the atomized powder comprises classifying the atomized powder such that the atomized powder has a median diameter of from 5 to 40 μm and 80% by volume or more of the atomized powder has a grain diameter of 50 μm or less.

(Invention 5)

The method according to Invention 3 or 4, wherein a temperature of the hot pressing is from 700° C. to 1600° C.

(Invention 6)

The method according to any one of Inventions 3 to 5, wherein the method further comprises a step of performing a HIP treatment at a temperature of from 700° C. to 1600° C. after the hot pressing.

(Invention 7)

The method according to any one of Inventions 3 to 6, wherein a Fe content is 0 mol % or more and 50 mol % or less.

(Invention 8)

The method according to any one of Inventions 3 to 7, wherein a Co content is 0 mol % or more and 50 mol % or less.

(Invention 9)

The method according to any one of Inventions 3 to 8, wherein a Cr content is 0 mol % or more and 50 mol % or less.

(Invention 10)

The method according to any one of Inventions 3 to 9, wherein a C content is 1₀ mol % or more and 70 mol % or less.

(Invention 11)

The method according to any one of Inventions 3 to 10, wherein the method further comprises a step of adding one or more metal materials selected from a group consisting of Ru, Ag, Au, Cu, and Ge.

(Invention 12)

The method according to any one of Inventions 3 to 11, wherein the method further comprises a step of adding one or more inorganic materials selected from a group consisting of oxides, nitrides other than BN, carbides, and carbonitrides.

(Invention 13)

A method for producing a magnetic recording medium, the method comprises:

a step of forming a magnetic thin film using the sputtering target according to Invention 1 or 2 or the sputtering target produced by the method according to any one of Inventions 3 to 12.

### Advantageous Effects of Invention

In one aspect, the sputtering target according to the present disclosure has a specific number of boundaries between the metallic phases and the nonmetallic phases on line segments each having a length of 500 μm in a horizontal direction and a vertical direction. This can provide outstanding effects that generation of particles can be suppressed during sputtering.

### BRIEF DESCRIPTION OF DRAWINGS

FIG. 1 is a SEM photograph of Fe—Pt atomized powder according to Example 1.

FIG. 2 is a SEM photograph of Co—Pt atomized powder according to Example 6.

FIG. 3 is a laser micrograph showing a target structure having a cross section perpendicular to a sputtering surface of Example 1 (in a field of view having a length of 560 μm and a width of 750 μm).

FIG. 4 is a laser micrograph showing a target structure having a cross section perpendicular to a sputtering surface of Comparative Example 1 (in a field of view having a length of 560 μm and a width of 750 μm).

FIG. 5 is a laser micrograph showing a target structure having a cross section perpendicular to a sputtering surface of Comparative Example 2 (in a field of view having a length of 560 μm and a width of 750 μm).

FIG. 6 shows an outline of a hot press.

### DESCRIPTION OF THE PREFERRED EMBODIMENTS

In one embodiment, a sputtering target according to the present disclosure has a structure in which one or more of C and BN are uniformly dispersed in metallic phases composed of one or more of Fe, Co, Cr, and Pt. The component composition of the sputtering target according to the present disclosure may satisfy one or more of the following concentration conditions (A) to (E):

(A) a Fe content of 0 mol % or more and 50 mol % or less (more preferably from 0 mol % to 30 mol %);

(B) a Co content of 0 mol % or more and 50 mol % or less (more preferably from 0 mol % to 30 mol %);

(C) a Cr content of 0 mol % or more and 50 mol % or less (more preferably from 0 mol % to 20 mol %);

(D) a C content of 10 mol % or more and 70 mol % or less (more preferably from 40 mol % or less); and

(E) a BN content of 0 mol % or more and 60 mol % or less (more preferably from 0 mol % to 40 mol %).

Moreover, the balance other than the above elements is preferably Pt (of course, when the total content of the above elements is 100%, Pt may be absent). If the contents are beyond the composition ranges, desired magnetic properties may not be obtained.

In a preferred embodiment, it is effective to, in addition to the above components, contain 0.5 mol % or more and 15 mol % or less (more preferably from 0.5 mol % to 1₀ mol %) of at least one element selected from the group consisting of Ru, Ag, Au, Cu, and Ge as an additive element in order to improve magnetic properties. Furthermore, in addition to the above components, one or more inorganic materials selected from the group consisting of oxides, nitrides (excluding BN described above), carbides, carbonitrides may be added as an additive to further increase magnetic properties.

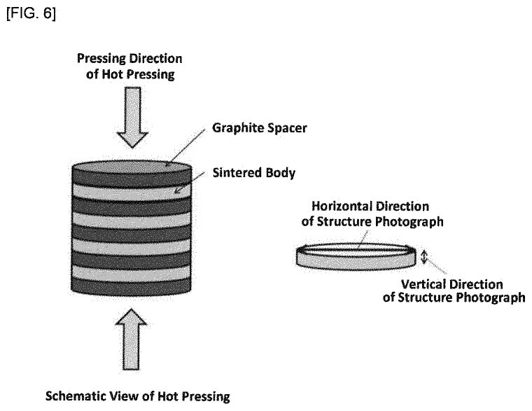

In one embodiment, the sputtering target according to the present disclosure can have a specific structure. More specifically, the number of boundaries between the metallic phases and the nonmetallic phases on a line segment having a length of 500 μm drawn in a vertical direction in a structure photograph is 40 or less (more preferably 30 or less). Here, the vertical direction refers to a direction perpendicular to the sputtering surface (FIG. 6). In a further embodiment, a ratio of the number of boundaries between the metallic phases and the nonmetallic phases on the line segment having a length of 500 μm drawn in the vertical direction to the number of boundaries between the metallic phases and the nonmetallic phases on a line segment having a length of 500 μm drawn in a horizontal direction is a specific value. More specifically, the ratio: (average number of boundaries in vertical direction)/(average number of boundaries in horizontal direction) is 1.7 or less (more preferably 1.5 or less). Here, the horizontal direction refers to a direction parallel to the sputtering surface (FIG. 6).

In order to reduce particles, it is important to uniformly disperse atomized powder and raw material powder such as C and BN. Therefore, it is important to realize a state where aggregation of C, BN and the like is reduced as much as possible. From such a point of view, when the number(s) of boundaries between the metallic phases and the nonmetallic phases on the line segment(s) having a length of 500 μm drawn in the vertical direction and/or the horizontal direction is/are increased, for example, when the number of boundaries in the vertical direction is more than 40, aggregation of C or BN is increased, and an increase in particles becomes significant. However, as shown in FIG. 6, the atomized powder is crushed in the vertical direction due to pressurization by the hot pressing during sintering. Therefore, the number of boundaries in the vertical direction is larger than the number of boundaries in the horizontal direction. However, if the ratio: (average value of boundaries in vertical direction)/(average value of the boundaries in horizontal direction) is more than 1.7, the aggregation of C or BN is increased, and an increase in particles becomes remarkable.

A method for producing the sputtering target according to one embodiment of the present disclosure will be now described.

First, one or more metal raw materials of Fe, Co, Cr, and Pt are introduced into a crucible and melted. A ratio of the raw materials can be appropriately adjusted according to the desired composition. Moreover, as a melting material, a previously alloyed material can also be used. The molten alloy is caused to flow out of a small hole in the crucible to form a narrow flow, and a high-speed gas is blown onto the narrow flow to scatter and rapidly solidify the molten metal to produce atomized powder. If the grain diameter of the atomized powder is too large, the raw material graphite will be difficult to disperse. Therefore, the atomized powder preferably has a median diameter of 40 μm or less (more preferably 25 μm or less). On the other hand, if the grain diameter of the atomized powder is too small, there is a problem that oxidation easily proceeds in the atmosphere. Therefore, the atomized powder more preferably has a median diameter of 5 μm or more (even more preferably 10 μm or more). As a method for controlling the median diameter, classification can be carried out after the atomization processing to provide atomized powder having a desired grain diameter. As the classification means, a classification device may be used, or a sieve may be used.

More preferably, the atomized powder is adjusted such that the powder having a grain diameter of 50 μm or less is 80% by volume or more (more preferably 95% by volume or more). This can allow the atomized powder having a larger grain diameter to be eliminated, and prevent the raw material graphite from becoming difficult to disperse.

A lead time required for the production of the atomized powder is at most about 4 to 5 hours from preparation to completion of the powder, although it depends on the size of the atomizing apparatus. Therefore, the lead time can be greatly shortened as compared with the pulverized chip powder that requires ten days for production. Further, the production cost is approximately 300,000 yen per a target for the pulverized chip powder, whereas the cost is approximately 150,000 yen for the atomized powder, resulting in significant reduction of cost. Furthermore, the atomized powder can form a uniform structure more easily as compared with the pulverized chip powder, and the uniform structure is effective for stabilizing electric discharge during sputtering and reducing particles.

Further, one or more metal raw materials of Fe, Co, Cr, and Pt may be added in the form of powder to the atomized powder separately from the atomized powder.

For the C raw material powder, flat or flaky graphite or exfoliated graphite (graphite having a small number of graphite layers) is preferably used. Since the exfoliated graphite has a better electric conduction than that of general graphite, it is effective for suppressing abnormal electric discharge and reducing particles. The exfoliated graphite may be called scaly graphite, scale-shaped graphite, or expanded graphite. The same effect can be expected using any of these graphites. The C raw material powder preferably has a median diameter of 0.5 μm or more and 30 μm or less. If the C raw material are too fine, the C raw materials aggregate together, which is not preferable. If the C raw materials are too large, the C raw materials themselves cause abnormal electric discharge, which is not preferable.

For the BN raw material powder, both hexagonal BN and cubic BN may be used. The cubic BN is preferable because it is very hard and does not cause defects during mixing. The BN raw material powder that can be preferably used has a median diameter of 0.5 μm or more and 30 μm or less. If the BN raw materials are too fine, the BN raw materials undesirably aggregate together, and if the BN raw materials are too large, the BN raw materials themselves cause abnormal electric discharge, which is not preferable.

The above atomized powder, C raw material powder and/or BN raw material powder are then weighed so as to have a desired composition, and these powders are mildly mixed using a mortar or a sieve having an opening of from 150 to 400 μm. As used herein, the wording “mildly mixed” or “mild mixing” means mixing so as not to provide the crystal structure of C or BN with defects as much as possible, and means, for example, a mixing method in which these powders pass through a sieve having an opening of from 150 to 400 μm five times. In addition, the size of the opening of the sieve can be selected according to the particle diameters of the raw materials to be used.

In a case where the metal materials such as Ru, Ag, Au, Cu and Ge, or inorganic materials such as oxides, nitrides (except for BN), carbides and carbonitrides are added, they are preferably mixed together at the same timing as that of the addition of C or BN. These raw material powders preferably have a median diameter of 0.5 μm or more and 30 μm or less (more preferably from 0.5 μm to 10 μm). If the grain diameter is too small, the raw materials aggregates together, which is not preferable. If the grain diameter is too large, the raw materials themselves cause abnormal electric discharge, which is not preferable.

As described above, the use of the atomized powder with a controlled particle diameter, one or more powders of C or BN, and inorganic material powder optionally added can shorten the lead time, reduce costs, and reduce particles during sputtering. The grain diameter of the raw material powder is a value measured using a wet particle size distribution meter from HORIBA (LA-920 from HORIBA) and using isopropyl alcohol as a dispersion solvent. More particularly, after introducing an appropriate amount of powder into the apparatus, an ultrasonic treatment is carried out for 3 minutes and the measurement is then started. A relative refractive index used during measurement is of Pt.

The mixed powder is then filled in a carbon mold, and molded and sintered by a hot press with uniaxial pressurization (FIG. 6). At the time of the hot press with such uniaxial pressurization, the C phases or the BN phases are aligned in a specific direction. The retention temperature during the hot pressing is preferably as high as possible, but in many cases, the temperature range is from 700° C. to 1600° C. (preferably from 700° C. to 1000° C.), in consideration of the fact that the retention temperature cannot exceed a melting point of the constituent material of the sputtering target. Moreover, a sintered body taken out from the hot press may be optionally subjected to hot isostatic pressing (HIP). The hot isostatic pressing is effective for improving the density of the sintered body. The retention temperature during the hot isostatic pressing is often in a temperature range of from 700° C. to 1600° C., depending on the composition of the sintered body, and more preferably 1000 or less in order to suppress thermal expansion amounts of the metallic phases and nonmetallic phases as much as possible. An applied pressure is set to 100 MPa or more. By processing the sintered body thus obtained into a desired shape with a lathe, the sputtering target of the present disclosure according to an embodiment can be produced. Using the sputtering target, a magnetic thin film can be formed under sputtering conditions known in the art. Thus, magnetic recording media can be produced.

### EXAMPLES

Hereinafter, the present invention will be described based on Examples and Comparative Examples. In addition, each Example is merely illustrative, and is not limited at all by those Examples. In other words, the present invention is limited only by the scope of the claims, and may include various modifications other than Examples included in the present invention.

### Example 1

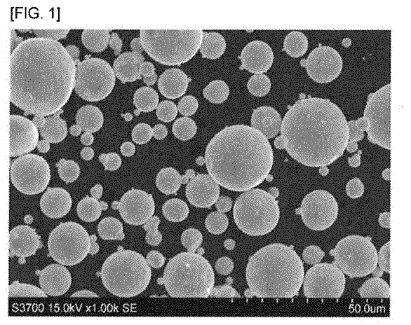

A Fe raw material and a Pt raw material were introduced into an atomizing apparatus so as to have a ratio of 50Fe-50Pt (at. %) and Fe—Pt atomized powder was prepared. The Fe—Pt atomized powder is shown in FIG. 1. The Fe—Pt atomized powder was then classified using a sieve having an opening of 150 μm. In order to examine a median diameter of the Fe—Pt atomized powder, the measurement was carried out using a wet particle size distribution diameter from HORIBA, using isopropyl alcohol as a dispersion solvent. As a result, the median diameter of Fe—Pt atomized powder was 16 μm, and the powder having a grain diameter of 50 μm or less was 95.0% by volume.

Exfoliated graphite powder having a median diameter of 25 μm was prepared, and the Fe—Pt atomized powder obtained as described above and the exfoliated graphite powder were mixed together using a sieve having an opening of 150 μm so as to have a composition ratio of 30Fe-30Pt-40C (mol %). The resulting mixture was filled in a carbon mold and hot-pressed. The hot pressing was carried out under conditions of a vacuum atmosphere, a retention temperature of 700° C., a retention time of 2 hours, and pressurization at 30 MPa from the start of temperature rising to the end of retention. After the end of the retention, it was naturally cooled in the furnace.

The sintered body taken out from the hot pressing mold was then subjected to hot isostatic pressing. The hot isostatic pressing was carried out under conditions of a retention temperature of 1100° C. and a retention time of 2 hours. A gas pressure of Ar gas was gradually increased from the start of the temperature rising, and a pressure of 150 MPa was applied during the retention at 1100° C. After the end of the retention, it was naturally cooled in the furnace.

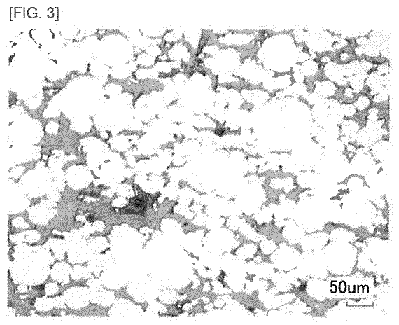

An edge of the resulting sintered body was cut out, a cross section perpendicular to the sputtering surface was polished, and its structure was observed with a laser microscope (VK9710, from Keyence Corporation). The magnification of an objective lens was 20 times, and the magnification of a digital zoom was 1. When photographing the structure at this magnification, the length is about 560 μm and the width is about 750 μm. In should be noted that an amount of light during the photographing is 30%, and an output is 834. Further, a Z position of the lens is set such that the entire field of view is included in the structure photograph. Auto focus may be used as needed. A structure image was taken at arbitrarily selected locations on the structure surface at the magnifications as described above, with the upper side of the structure image being the sputter surface and the lower side being the back surface. The photographed image is shown in FIG. 3. The white parts of the structure observation image correspond to the Fe—Pt phases. On the other hand, the black parts correspond to the C phases.

The sintered body was cut into a shape having a diameter of 180.0 mm and a thickness of 5.0 mm with a lathe, and then installed in a magnetron sputtering apparatus (C-3010 sputtering system from CANON ANELVA CORPORATION), and subjected to sputtering. The sputtering was carried out under conditions of an input power of 1 kW and an Ar gas pressure of 1.7 Pa. After performing pre-sputtering at 2 kWhr, a film was formed on a 4-inch diameter silicon substrate for 20 seconds. The number of particles adhering to the substrate was measured with a surface foreign matter inspection apparatus (CS-920 from KLA-Tencor). As a result, the number of particles was 100, which was significantly reduced as compared with Comparative Examples 1 and 2 described later.

The structure photograph as described above was subjected to binary coded processing. An image processing software used was VK Analyzer Ver. 1.2.0.2. First, a threshold value for binary coded processing is automatically set by the software. The reason is that an appropriate threshold value varies depending on the composition of the target. If photographing is performed with the light amount as defined above, a difference between photographers can be almost ignored. After the binary coded processing, any unnecessary noise is removed. Here, the noise is defined as a point having an area of 10 pixels or less. The noise removal is carried out for both the white and black points displayed on the binary coded screen. If only either one of the color noises can be removed due to software constraints, black and white inversion processing is performed, and both noises are then surely removed.

To the binary coded image thus created, 10 line segments each having a length of 500 μm and a thickness of 0.8 μm on the scale of the structure photograph are drawn in the vertical direction and the 10 line segments are also drawn in the same manner in the horizontal direction. The line segments are drawn as follows. First, how to draw the line segments in the vertical direction will be described. The starting point of a first line segment is at a position 25 μm from the upper end and 25 μm from the left end of the structure photograph. A direction of the first line segment should be parallel to the left side of the structure photograph. A length and thickness of the line segment are as described above. The starting point of the second line segment is at a point translated from the first starting point by 50 μm in the right direction, and a direction of the line segment should be parallel to the first line segment. From the third to the tenth line segments, each starting point of each line segment is spaced by 50 μm from the previous line segment. Next, how to draw the line segment in the horizontal direction will be described. The starting points of the first line segment is at a position 50 μm from the upper end and 15 μm from the left end of the structure photograph. A direction of the line segment should be parallel to the upper side of the structure photograph. A length and thickness of the line segment are as described above. The starting point of the second line segment is at a point translated from the first starting point by 50 μm in the downward direction, and a direction of the line segment should be parallel to the first line segment. From the third to the tenth line segments, each starting point of each line segment is spaced by 50 μm from the previous line segment. The number of boundaries between the white and black parts on those line segments was counted. Average values in the vertical direction and the horizontal direction were calculated, indicating that the average value of the boundaries on the line segments in the vertical direction was 20, and the average value of the boundaries on the line segments in the horizontal direction was 14. Further, a ratio: (average value in vertical direction)/(average value in horizontal direction) was calculated, indicating that it was 1.4.

### Example 2

The same test as that of Example 1 was conducted. However, changes from Example 1 were as follows. First, the composition ratio of the raw material of atomized powder was 10Fe-90Pt (at. %).

Next, as the materials to be mixed with atomized powder, the following powders were prepared:

Fe powder having a median diameter of 5 μm,

Ag powder having a median diameter of 3.5 μm,

Cu powder having a median diameter of 5 μm,

BN powder (cubic) having a median diameter of 8 μm, and

exfoliated graphite powder having a median diameter of 25 μm.

They were then mixed so as to have a composition ratio: 24Fe-24Pt-3Ag-9Cu-33BN-7C (mol %). The retention temperature was 700° C. as the hot pressing condition. The retention temperature for the hot isostatic pressing was 750° C.

The number of particles was measured, indicating that it was 120, which was significantly reduced as compared with Comparative Example 3 described later.

### Example 3

The same test as that of Example 1 was conducted. However, changes from Example 1 were as follows. First, the composition ratio of the raw material of atomized powder was 90Fe-10Pt (at. %).

Next, as the materials to be mixed with atomized powder, the following powders were prepared:

Pt powder having a median diameter of 6 μm,

Cu powder having a median diameter of 5 μm, and

exfoliated graphite powder having a median diameter of 25 μm.

They were then mixed so as to have a composition ratio: 15Fe-15Pt-5Cu-65C (mol %).

The retention temperature was 900° C. as the hot pressing condition. The retention temperature for the hot isostatic pressing was 900° C.

### Example 4

The same test as that of Example 1 was conducted. However, changes from Example 1 were as follows. First, the composition ratio of the raw material of atomized powder was 37.5Fe-25Co-37.5Pt (at. %).

Next, as the material to be mixed with atomized powder, BN powder (cubic) having a median diameter of 10 μm was prepared. They were then mixed so as to have a composition ratio: 30Fe-20Co-30Pt-20BN (mol %). The retention temperature was 1100° C. as the hot pressing condition. The retention temperature for the hot isostatic pressing was 1100° C.

### Example 5

The same test as that of Example 1 was conducted. However, changes from Example 1 were as follows. First, the composition ratio of the raw material of atomized powder was 90Co-10Pt (at. %).

They were then mixed so as to have a composition ratio: 63Co-7Pt-30C (mol %). The retention temperature was 1050° C. as the hot pressing condition. The retention temperature for the hot isostatic pressing was 1100° C.

### Example 6

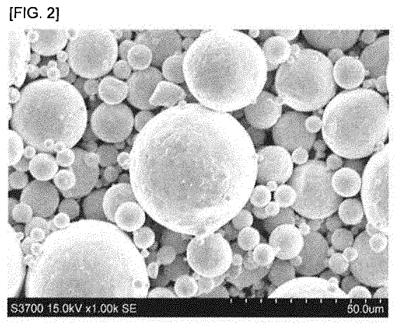

The same test as that of Example 1 was conducted. However, changes from Example 1 were as follows. First, the composition ratio of the raw material of atomized powder (see FIG. 2) was 20Co-80Pt (at. %).

Next, as the materials to be mixed with atomized powder, the following powders were prepared:

Cr powder having a median diameter of 10 μm, and

exfoliated graphite powder having a median diameter of 25 μm.

They were then mixed so as to have a composition ratio: 16Co-10Cr-64Pt-10C (mol %).

The retention temperature was 1050° C. as the hot pressing condition. The retention temperature for the hot isostatic pressing was 1100° C.

The number of particles was measured, indicating that it was 130, which was significantly reduced as compared with Comparative Example 4 described later.

### Example 7

The same test as that of Example 1 was conducted. However, changes from Example 1 were as follows. First, the composition ratio of the raw material of atomized powder was 17.8Co-11.1Cr-71.1Pt (at. %).

Next, a material to be mixed with the atomized powder was then mixed so as to have a composition ratio: 16Co-10Cr-64Pt-10C (mol %). The retention temperature was 1050° C. as the hot pressing condition. The retention temperature for the hot isostatic pressing was 1050° C.

The number of particles was measured, indicating that it was 170, which was significantly reduced as compared with Comparative Example 4 described later.

### Example 8

The same test as that of Example 1 was conducted. However, changes from Example 1 were as follows. First, the composition ratio of the raw material of atomized powder was 60Fe-40Pt (at. %).

Next, as the materials to be mixed with atomized powder, the following powders were prepared:

Ge powder having a median diameter of 30 μm, and

exfoliated graphite powder having a median diameter of 25 μm.

They were then mixed so as to have a composition ratio: 31.2Fe-20.8Pt-8Ge-40C (mol %). The retention temperature was 750° C. as the hot pressing condition. The retention temperature for the hot isostatic pressing was 750° C.

The number of particles was measured, indicating that it was 130, which was significantly reduced as compared with Comparative Example 5 described later.

### Example 9

The same test as that of Example 1 was conducted. However, changes from Example 1 were as follows. First, the composition ratio of the raw material of atomized powder was 100Fe (at. %).

Next, as the material to be mixed with atomized powder, exfoliated graphite powder having a median diameter of 25 μm was prepared. They were then mixed so as to have a composition ratio: 40Fe-60C (mol %). The retention temperature was 1100° C. as the hot pressing condition. The retention temperature for the hot isostatic pressing was 1100° C.

The number of particles was measured, indicating that it was 110, which was significantly reduced as compared with Comparative Example 6 described later.

### Example 10

The same test as that of Example 1 was conducted. However, changes from Example 1 were as follows. First, the composition ratio of the raw material of atomized powder was 50Co-50Pt (at. %).

Next, as the materials to be mixed with atomized powder, the following powders were prepared:

Ru powder having a median diameter of 10 μm, and

exfoliated graphite powder having a median diameter of 25 μm.

They were then mixed so as to have a composition ratio: 25Co-25Pt-10Ru-40C (mol %).

The retention temperature was 1100° C. as the hot pressing condition. The retention temperature for the hot isostatic pressing was 1100° C.

### Comparative Example 1

First, an Fe raw material and a Pt raw material were melted by vacuum melting and casting to obtain an alloy ingot having a composition ratio of 50Fe-50Pt (at. %), which was in a cylindrical shape having about φ150. A surface oxide film on the resulting alloy ingot was then removed, and the ingot was then set onto a general-purpose lathe and cut with a cutting depth of 0.3 mm to produce Fe—Pt alloy chips.

Subsequently, the Fe—Pt alloy chips were pulverized using a Brown horizontal pulverizer such that they passed through a sieve having an opening of 150 μm, and fine grains were then removed using a sieve having an opening of 63 μm. Further, the Fe—Pt pulverized powder was introduced into a medium stirring mill having a tank capacity of 5 L, and a treatment was carried out using yttria-stabilized zirconia beads having a diameter of 5 mm as pulverizing media for 4 hours to prepare dense exfoliated Fe—Pt alloy powder.

In order to investigate the median diameter of the dense exfoliated Fe—Pt alloy powder, the median diameter was measured using a wet particle size distribution meter from HORIBA using isopropyl alcohol as a dispersion solvent. As a result of measurement, the median diameter of the dense Fe—Pt alloy powder was 85 μm.

Exfoliated graphite powder having a median diameter of 25 μm was then prepared, and the dense Fe—Pt alloy powder obtained above and the exfoliated graphite powder were mixed together using a sieve having an opening of 400 μm so as to have a composition ratio: 30Fe-30Pt-40C (mol %). The mixture was then filled in a carbon mold, and hot-pressed.

The hot pressing was carried out under conditions of a vacuum atmosphere, a retention temperature of 700° C., a retention time of 2 hours, and pressurization at 30 MPa from the start of temperature rising to the end of retention. After the end of the retention, it was naturally cooled in the furnace.

A sintered body taken out from the hot press mold was then subjected to hot isostatic pressing. The hot isostatic pressing was carried out under conditions of a retention temperature of 1100° C. and a retention time of 2 hours. A gas pressure of Ar gas was gradually increased from the start of the temperature rising, and a pressure of 150 MPa was applied during the retention at 1100° C. After the end of the retention, it was naturally cooled in the furnace.

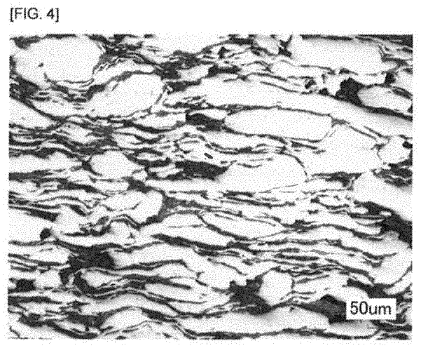

The subsequent steps were carried out under the same conditions as those of Example 1. The structure cross section is shown in FIG. 4.

### Comparative Example 2

Fe powder having a median diameter of 5 μm, Pt powder having a median diameter of 6 μm, and exfoliated graphite powder having a median diameter of 25 μm were prepared, and these were mixed using a sieve having an opening of 150 μm so as to have a composition ratio: 30Fe-30Pt-40 C (mol %). The resulting mixture was filled in a carbon mold and hot-pressed.

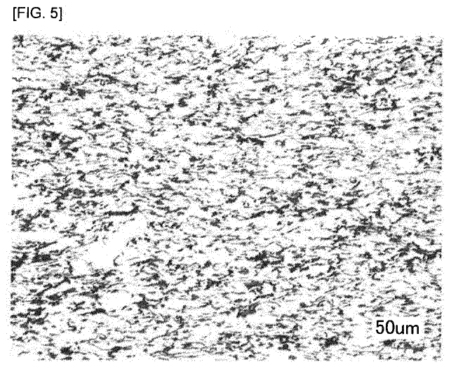

The retention temperature was 700° C. as a hot press condition. The retention temperature for the hot isostatic pressing was 1100° C. The subsequent steps were carried out under the same conditions as those of Comparative Example 1. A structure cross section is shown in FIG. 5.

### Comparative Example 3

Fe powder having a median diameter of 5 μm, Pt powder having a median diameter of 6 μm, Ag powder having a median diameter of 3.5 μm, Cu powder having a median diameter of 5 μm, BN powder (cubic) having a median diameter of 10 μm, and exfoliated graphite powder having a median diameter of 25 μm were prepared. These were mixed using a sieve having an opening of 150 μm so as to have a composition ratio: 5Fe-45Pt-2Ag-9Cu-33BN-60 (mol %). The mixture was filled in a carbon mold, and hot-pressed.

The retention temperature was 700° C. as a hot press condition. The retention temperature for the hot isostatic pressing was 750° C. The subsequent steps were carried out under the same conditions as those of Comparative Example 1.

### Comparative Example 4

Co powder having a median diameter of 3.5 μm, Cr powder having a median diameter of 8 μm, Pt powder having a median diameter of 6 μm, and exfoliated graphite powder having a median diameter of 25 μm were prepared. These were mixed using a sieve having an opening of 150 μm so as to have a composition ratio: 16Co-10Cr-64Pt-10C (mol %). The mixture was filled in a carbon mold, and hot-pressed.

The retention temperature was 1050° C. as a hot press condition. The retention temperature for the hot isostatic pressing was 1100° C. The subsequent steps were carried out under the same conditions as those of Comparative Example 1.

### Comparative Example 5

Fe powder having a median diameter of 5 μm, Pt powder having a median diameter of 6 μm, Ge powder having a median diameter of 30 μm, and exfoliated graphite powder having a median diameter of 25 μm were prepared. These were mixed using a sieve having an opening of 150 μm so as to have a composition ratio: 31.2Fe-20.8Pt-8Ge-40C (mol %). The mixture was filled in a carbon mold, and hot-pressed.

The retention temperature was 750° C. as a hot press condition. The retention temperature for the hot isostatic pressing was 750° C. The subsequent steps were carried out under the same conditions as those of Comparative Example 1.

### Comparative Example 6

Fe powder having a median diameter of 5 μm and exfoliated graphite powder having a median diameter of 25 μm were prepared. These were mixed using a sieve having an opening of 150 μm so as to have a composition ratio: 40Fe-60C (mol %). The mixture was filled in a carbon mold, and hot-pressed.

The retention temperature was 1100° C. as a hot press condition. The retention temperature for the hot isostatic pressing was 1100° C. The subsequent steps were carried out under the same conditions as those of Comparative Example 1.

The results are shown in Table 1.

TABLE 1

| | | | | Ratio of Grain | |
|---|---|---|---|---|---|
| | | Atomized Powder | Atomized | Diameter of | |
| | | Raw Material | Powder Median | 50 μm or less | Raw Material Composition Ratio after |
| | | Composition Ratio (at %) | Diameter (μm) | (% by volume) | Mixing with Carbon Powder, etc (mol %) |
| Example | 1 | 50Fe—50Pt | 16 | 95.0 | 30Fe—30Pt—40C |
| Example | 2 | 10Fe—90Pt | 16 | 95.0 | 24Fe—24Pt—3Ag—9Cu—33BN—7C |
| Example | 3 | 90Fe—10Pt | 40 | 95.0 | 15Fe—15Pt—5Cu—65C |
| Example | 4 | 37.5Fe—25Co—37.5Pt | 16 | 85.0 | 30Fe—20Co—30Pt—20BN |
| Example | 5 | 90Co—10Pt | 18 | 90.0 | 63Co—7Pt—30C |
| Example | 6 | 20Co—80Pt | 14 | 98.0 | 16Co—10Cr—64Pt—10C |
| Example | 7 | 17.8Co—11.1Cr—71.1Pt | 25 | 90.0 | 16Co—10Cr—64Pt—10C |
| Example | 8 | 60Fe—40Pt | 17 | 95.0 | 31.2Fe—20.8Pt—8Ge—40C |
| Example | 9 | 100Fe | 18 | 95.0 | 40Fe—60C |
| Example | 10 | 50Co—50Pt | 17 | 95.0 | 25Co—25Pt—10Ru—40C |
| Comparative | 1 | 50Fe—50Pt | 85 | | 30Fe—30Pt—40C |
| Example | | | | | |
| Comparative | 2 | | | | 30Fe—30Pt—40C |
| Example | | | | | |
| Comparative | 3 | | | | 5Fe—45Pt—2Ag—9Cu—33BN—6C |
| Example | | | | | |
| Comparative | 4 | | | | 16Co—10Cr—64Pt—10C |
| Example | | | | | |
| Comparative | 5 | | | | 31.2Fe—20.8Pt—8Ge—40C |
| Example | | | | | |
| Comparative | 6 | | | | 40Fe—60C |
| Example | | | | | |

| | | | Number of | Number of | | |
|---|---|---|---|---|---|---|
| | | Hot Press | Boundaries | Boundaries | | |
| | | Temperature | (Vertical | (Horizontal | | Number of |
| | | (° C.) | Direction) | Direction) | Ratio | Particles |
| Example | 1 | 700 | 20 | 14 | 1.4 | 100 |
| Example | 2 | 700 | 16 | 12 | 1.3 | 120 |
| Example | 3 | 900 | 11 | 8 | 1.4 | 160 |
| Example | 4 | 1100 | 29 | 19 | 1.5 | 90 |
| Example | 5 | 1050 | 23 | 14 | 1.6 | 150 |
| Example | 6 | 1050 | 16 | 13 | 1.2 | 130 |
| Example | 7 | 1050 | 26 | 18 | 1.4 | 170 |
| Example | 8 | 750 | 19 | 14 | 1.4 | 130 |
| Example | 9 | 1100 | 21 | 14 | 1.5 | 110 |
| Example | 10 | 1100 | 20 | 14 | 1.4 | 110 |
| Comparative | 1 | 700 | 48 | 20 | 2.4 | 520 |
| Example | | | | | | |
| Comparative | 2 | 700 | 92 | 40 | 2.3 | 1020 |
| Example | | | | | | |
| Comparative | 3 | 700 | 103 | 42 | 2.5 | 960 |
| Example | | | | | | |
| Comparative | 4 | 1050 | 103 | 42 | 2.5 | 1160 |
| Example | | | | | | |
| Comparative | 5 | 750 | 49 | 21 | 2.3 | 600 |
| Example | | | | | | |
| Comparative | 6 | 1100 | 50 | 19 | 2.6 | 780 |
| Example | | | | | | |

21585731.2

### INDUSTRIAL APPLICABILITY

The invention according to an embodiment of the present disclosure relates to a sputtering target including magnetic phases composed of one or more alloys of Fe, Co, Cr, and Pt and nonmagnetic phases separating them and being composed of one or more of C and BN, and to a method for producing the same, which has advantageous effects that can shorten the lead time required for the production of the raw material powder, can reduce costs and can suppress generation of particles during sputtering. The invention according to an embodiment of the present disclosure is useful for ferromagnetic sputtering targets for forming magnetic thin films of magnetic recording media, particularly granular type magnetic recording layers.

1. A sputtering target comprising:
one or more metallic phases selected from a group consisting of Fe, Co, Cr, and Pt; and
one or more nonmetallic phases selected from a group consisting of C and BN,
wherein the sputtering target satisfies:
A≤40, and
A/B≤1.7
in which:
A represents the number of boundaries between the metallic phases and the nonmetallic phases on a line segment having a length of 500 μm drawn in a vertical direction, in a structure photograph; and
B represents the number of boundaries between the metallic phases and the nonmetallic phases on a line segment having a length of 500 μm drawn in a horizontal direction, in the structure photograph.

2. The sputtering target according to claim 1, wherein the sputtering target further comprises one or more metals selected from a group consisting of Ru, Ag, Au, Cu, and Ge.

3. A method for producing the sputtering target according to claim 1, comprising:
a step of atomizing one or more metals selected from a group consisting of Fe, Co, Cr, and Pt to obtain atomized powder;
a step of processing the atomized powder so as to have a median diameter of 40 μm or less;
a step of mixing the atomized powder with at least one powder selected from a group consisting of C and BN; and
a step of sintering the mixed powder by hot pressing.

4. The method according to claim 3, wherein the step of processing the atomized powder comprises classifying the atomized powder such that the atomized powder has a median diameter of from 5 to 40 μm and 80% by volume or more of the atomized powder has a grain diameter of 50 μm or less.

5. The method according to claim 3, wherein a temperature of the hot pressing is from 700° C. to 1600° C.

6. The method according to claim 3, wherein the method further comprises a step of performing a HIP treatment at a temperature of from 700° C. to 1600° C. after the hot pressing.

7. The method according to claim 3, wherein a Fe content is 0 mol % or more and 50 mol % or less.

8. The method according to claim 3, wherein a Co content is 0 mol % or more and 50 mol % or less.

9. The method according to claim 3, wherein a Cr content is 0 mol % or more and 50 mol % or less.

10. The method according to claim 3, wherein a C content is 10 mol % or more and 70 mol % or less.

11. The method according to claim 3, wherein the method further comprises a step of adding one or more metal materials selected from a group consisting of Ru, Ag, Au, Cu, and Ge.

12. The method according to claim 3, wherein the method further comprises a step of adding one or more inorganic materials selected from a group consisting of oxides, nitrides other than BN, carbides, and carbonitrides.

13. A method for producing a magnetic recording medium, the method comprises:
a step of forming a magnetic thin film using the sputtering target according to claim 1.

14. A method for producing a magnetic recording medium, the method comprises:
a step of forming a magnetic thin film using the sputtering target produced by the method according to claim 3.
